(19) United States
(12) Patent Application Publication
(10) Pub. No.: US 2024/0014281 A1
(43) Pub. Date: Jan. 11, 2024

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Sheng-Feng Huang, Taoyuan City (TW); Kam-Tou Sio, Hsinchu County (TW); Jiann-Tyng Tzeng, Hsin Chu (TW); Shang-Wei Fang, Hsinchu City (TW); Chun-Yen Lin, Hsinchu City (TW)

(73) Assignee: Taiwan Semiconductor Manufacturing Company, Ltd., Hsinchu (TW)

(21) Appl. No.: 17/862,372

(22) Filed: Jul. 11, 2022

(51) Int. Cl. H01L 29/423; H01L 29/08; H01L 21/8234

(52) U.S. Cl. CPC H01L 29/42392; H01L 29/0847; H01L 21/823418

(57) ABSTRACT

Provided are a semiconductor device and a method of forming the same. The semiconductor device includes: at least one gate structure having a first side and a second side opposite to each other; a first source/drain (S/D) feature disposed at the first side of the at least one gate structure; a second S/D feature disposed at the second side of the at least one gate structure; a first metal-to-drain/source (MD) contact disposed on the first S/D feature; and a second MD contact disposed on the second S/D feature, wherein a contact area between the first MD contact and the first S/D feature is greater than a contact area between the second MD contact and the second S/D feature.

### BACKGROUND

The integrated circuit (IC) industry has experienced exponential growth. Technological advances in IC materials and design have produced generations of ICs, where each generation has smaller and more complex circuits than the previous generation. In the course of IC evolution, functional density (i.e., the number of interconnected IC devices per chip area) has generally increased while geometry size (i.e., dimensions and/or sizes of IC features and/or spacings between these IC features) has decreased. Typically, scaling down has been limited only by an ability to lithographically define IC features at the ever-decreasing geometry sizes. However, resistance-capacitance (RC) delay has arisen as a significant challenge as reduced geometry sizes are implemented to achieve ICs with faster operating speeds (e.g., by reducing distances traveled by electrical signals), thereby negating some of the advantages achieved by scaling down and limiting further scaling down of ICs. RC delay generally indicates delay in electrical signal speed through an IC resulting from a product of resistance (R) (i.e., a material's opposition to flow of electrical current) and capacitance (C) (i.e., a material's ability to store electrical charge). Reducing both resistance and capacitance is thus desired to reduce RC delay and optimize performance of scaled down ICs. Interconnects of ICs, which physically and/or electrically connect IC components and/or IC features of the ICs, are particularly problematic in their contributions to RC delay. A need thus exists for improvements in interconnects of ICs and/or methods of fabricating interconnects of ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a simplified top-down layout view of a semiconductor device in accordance with some embodiments.

FIG. 1B is a cross-sectional view of a semiconductor device in FIG. 1A.

FIG. 2 is a simplified top-down layout view of a semiconductor device in accordance with some embodiments.

FIG. 3A to FIG. 3C are cross-sectional views of a method of forming a semiconductor device in FIG. 2 taken along the line I-I′ in accordance with some embodiments.

FIG. 4 is a simplified top-down layout view of a semiconductor device in accordance with some alternative embodiments.

FIG. 5A is a simplified top-down layout view of a semiconductor device in accordance with some other embodiments.

FIG. 5B is a cross-sectional view of a semiconductor device in FIG. 5A.

FIG. 6 is a simplified top-down layout view of a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

IC manufacturing process flow is typically divided into three categories: front-end-of-line (FEOL), middle-of-line (MOL or MEOL), and back-end-of-line (BEOL). FEOL generally encompasses processes related to fabricating IC devices (e.g., transistors, resistors, capacitors, and/or inductors) on a wafer. For example, FEOL processes include forming isolation features, gate structures, and source/drain features. BEOL generally encompasses processes related to fabricating metallization layers that electrically connect IC devices and/or components of the IC devices (e.g., gate structures and/or source/drain features) fabricated during FEOL to one another and/or external devices, thereby enabling operation of the IC devices. The metallization layers can route signals between the IC devices and/or the components of the IC devices and/or distribute signals (e.g., clock signals, voltage signals, and/or ground signals) to the IC devices and/or the components of the IC devices. Often, each metallization layer (also referred to as a metallization level) includes at least one interconnect structure disposed in an insulator layer, such as a metal line and a via disposed in a dielectric layer, where the via connects the metal line to a metal line of an interconnect in a different metallization layer. Metal lines and vias of the metallization layers can be referred to as BEOL features or global interconnects. MOL generally encompasses processes related to fabricating contacts that physically and/or electrically connect FEOL features (e.g., electrically active features of the IC devices) to a first metallization layer (level) formed during BEOL, such as contacts that connect a gate structure and/or source/drain features of a transistor to the first metallization layer. Contacts fabricated during MOL can be referred to as device-level contacts and/or local interconnects. Sometimes, MOL involves forming a multi-layer MOL interconnect structure in an insulator layer, such as a first contact and a second contact disposed in a dielectric layer, where the first contact connects an electrically active feature of an IC device to the second contact and the second contact connects the first contact to the first metallization layer. The first contact and the second contact can be referred to as a device-level contact and a local contact (or interconnect), respectively.

As IC technologies progress towards smaller technology nodes, resistance and capacitance associated with global interconnects and local interconnects have presented challenges to reducing resistance-capacitance (RC) delay of the IC devices. For example, it has been observed that higher contact resistances and capacitances exhibited by MOL interconnect structures in advanced IC technology nodes can significantly delay (and, in some situations, prevent) signals from being routed efficiently to and from IC devices, such as transistors, negating any improvements in performance achieved by scaling down and limiting further scaling down of ICs.

In accordance with some embodiments, a dynamic metal-to-device (MD) width and poly pitch layout design is proposed to reduce the resistance at the device source-side and reduce the capacitance at the device drain-side compared to conventional MOL interconnect structures, thereby decreasing RC delay and improving IC device performance for advanced IC technology nodes. The present disclose further proposes fabrication techniques of forming the semiconductor device with the dynamic MD width and poly pitch design.

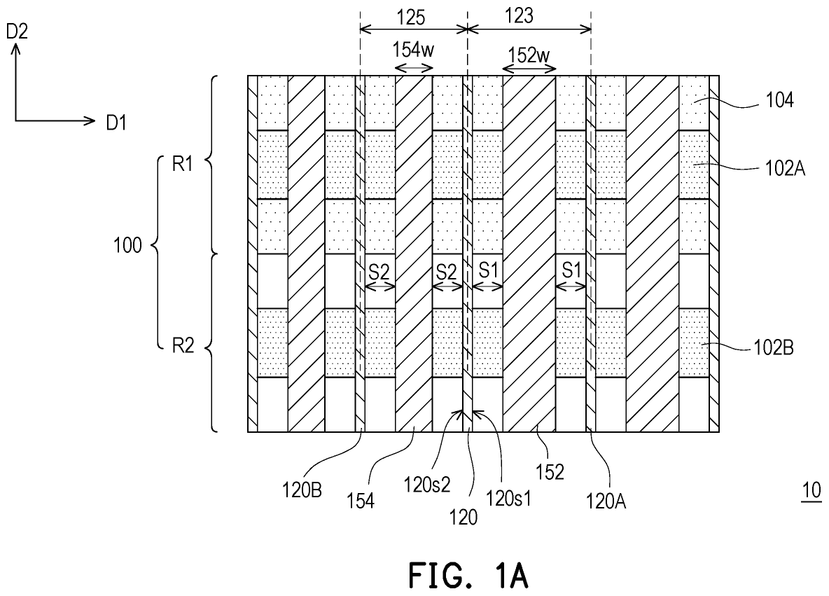

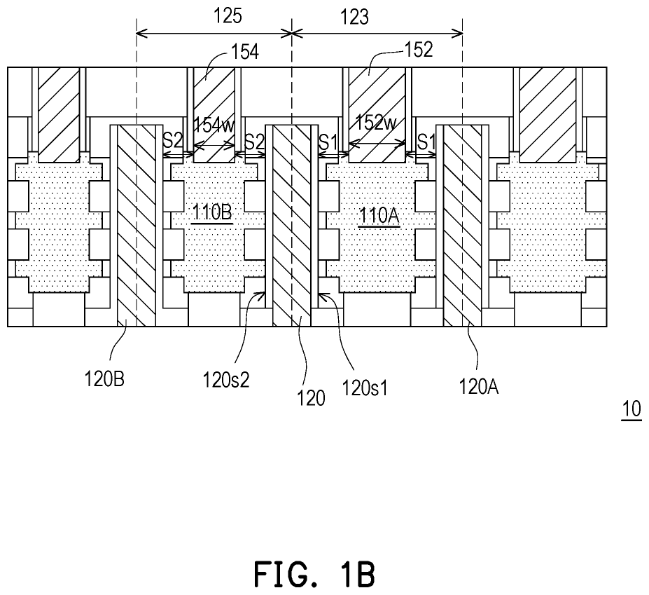

FIG. 1A is a simplified top-down layout view of a semiconductor device in accordance with some embodiments. FIG. 1B is a cross-sectional view of a semiconductor device in FIG. 1A.

Referring to FIG. 1A and FIG. 1B, a semiconductor device 10 may include be included in a microprocessor, a memory, and/or other IC devices. In some embodiments, the semiconductor device 10 is a portion of an IC chip, a system on chip (SoC), or portion thereof, that includes various passive and active microelectronic devices such as resistors, capacitors, inductors, diodes, p-type FETs (PFETs), n-type FETs (NFETs), metal-oxide-semiconductor FETs (MOSFETs), complementary MOS (CMOS) transistors, bipolar junction transistors (BJTs), laterally diffused MOS (LDMOS) transistors, high voltage transistors, high frequency transistors, other suitable components, or combinations thereof. The various transistors may be planar transistors or non-planar transistors, such as fin-like FETs (FinFETs) or gate-all-around (GAA) transistors depending on design requirements of the semiconductor device 10.

In detail, the semiconductor device 10 may include a substrate 100. In some embodiments, the substrate 100 includes a first region R1 and a second region R2. The first region R1 may include a first-type transistor, and the second region R2 may include a second-type transistor different than the first-type transistor. For example, the first region R1 may include p-type FETs (PFETs), while the second region R2 may include n-type FETs (NFETs). In such embodiment, the first region R1 may include a well region (e.g., n-well) 104 in the p-type substrate 100. In addition, the first region R1 may have an active region (also known as an oxide-dimensioned (OD) region) 102A extending along a first direction D1, the second region R2 may an active region 102B extending along the first direction D1, and the active region 102A may be separated from the active region 102B in a second direction D2 by an isolation structure (not shown). In some embodiments, the active regions 102A and 102B may be semiconductor fins for FinFETs, stacked semiconductor nanosheets for GAA transistors, or the like.

In some embodiments, the semiconductor device 10 includes a plurality of gate structures 120 extending along the second direction D2 and arranged alternately along the first direction D1 which is substantially perpendicular to the second direction D2. Specifically, each gate structure 120 may include a single-layered or multi-layered configurations, including one or more of interfacial layer, a High-K layer, a work function layer, a blocking layer, an adhesion layer, and a metal filling layer. The gate structure 120 may be made of Ti, Ag, Al, HfO, AlTiC, AlTiO, AlTiN, AlTiC, AlTiO, TiAlN, TaC, TaCN, TaSiN, Mn, Zr, TiN, TaN, Ru, Mo, Al, WN, Cu, W, or any suitable materials. The gate structure 120 may be formed by performing one or more of atomic layer deposition (ALD), physical vapor deposition (PVD), chemical vapor deposition (CVD), or other suitable process. As shown in FIG. 1A, the gate structure 120 may have a first side 120s1 and a second side 120s2 opposite to each other.

As shown in FIG. 1B, the semiconductor device 10 may also include a first source/drain (S/D) feature 110A, a second S/D feature 110B, a first metal-to-drain/source (MD) contact 152, and a second MD contact 154. In detail, the first S/D feature 110A may be disposed at the first side 120s1 of the gate structure 120 and the second S/D feature 110B disposed at the second side 120s2 of the gate structure 120. In some embodiments, the first and second S/D features 110A and 110B may be epitaxial S/D features including a semiconductor material epitaxially grown on and/or from the substrate 100, such as SiGe. The first MD contact 152 may be disposed on the first S/D feature 110A and the second MD contact 154 is disposed on the second S/D feature 110B. The first and second MD contacts 152, 154 may be metal electrodes electrically coupled with the first and second S/D features 110A, 110B, respectively. In some embodiments, the first and second MD contacts 152, 154 may include cobalt (Co), ruthenium (Ru), tungsten (W), or other suitable conductive material.

In some embodiments, as shown in FIG. 1A and FIG. 1B, a first pitch (also known as a poly pitch (CPP)) 123 is between the gate structure 120 and the adjacent gate structure 120A, and a second pitch 125 is between the gate structure 120 and the adjacent gate structure 120B. In addition, a first space S1 may be between the first MD contact 152 and the gate structure 120, and a second space S2 may be between the second MD contact 154 and the gate structure 120. Further, the first MD contact 152 may have a first width 152w, and the second MD contact 154 may have a second width 154w different from the first width 152w. For example, when the first space S1 is substantially equal to the second space S2 and the first width 152w is greater than the second width 154w, the first pitch 123 is also greater than the second pitch 125. In this case, a contact area between the first MD contact 152 and the first S/D feature 110A is greater than a contact area between the second MD contact 154 and the second S/D feature 110B, so that the resistance between the first MD contact 152 and the first S/D feature 110A is reduced, thereby decreasing the RC delay and improving device performance. In such embodiment, the first S/D feature 110A may be referred to as a source region, and the lower resistance can facilitate the power transfer between power supply lines (e.g., VDD and/or VSS) and the source region 110A. In addition, the smaller second width 154w or the smaller second pitch 125 can be beneficial for the area shrinking.

In some embodiments, the first pitch 123 may be in a range of 50 nm to 60 nm, such as 54 nm; the second pitch 125 may be in a range of 40 nm to 50 nm, such as 46 nm, and a ratio of the first pitch 123 to the second pitch 125 may be in a range of 1 to 1.5. In some embodiments, the first space S1 may be in a range of 5 nm to 10 nm, such as 10 nm; the second space S2 may be in a range of 5 nm to 10 nm, such as 10 nm; and a ratio of the first space S1 to the second space S2 may be in a range of 1 to 2. In some embodiments, the first width 152w may be in a range of 10 nm to 20 nm, such as 16 nm; the second width 154w may be in a range of 10 nm to 20 nm, such as 12 nm; and a ratio of the first width 152w to the second width 154w may be in a range of 1 to 2.

As mentioned above, the first width 152w may be greater than the second width 154w. In such embodiment, when the second width 154w is regarded as a fixed width (W), and the first width 152w may be adjusted to be (W+ΔW), where ΔW is a width variation. As such, the first pitch 123 and/or the second pitch 125 (i.e., CPP) may be represented by the following formula:

CPP=Wₚₒ+W+n×W+2S, where Wₚₒ is the width of the gate structure 120, W is the fixed second width 154w, ΔW is the width variation, S is the first space S1 and/or the second space S2 (herein, S1=S2), and n is constant.

For example, when the width (Wₚₒ) of the gate structure 120 is fixed to 12 nm, the second width 154w of the second MD contact 154 is fixed to 12 nm, the second space S2 is fixed to 10 nm, and n is 0, the second pitch 125 is calculated as 44 nm. In addition, the first pitch 123 may be dynamically adjusted to 44+(n×ΔW) nm.

In some alternative embodiments, as the width of the MD contact increases, the benefit of the resistance reduction gained by increasing the width of the MD contact also decreases. In this case, the maximum and minimum values of the first pitch 123 and/or the second pitch 125 (i.e., CPP) may be represented by the following formula:
Wₚₒ+W+2S≤CPP≤Wₚₒ+Wₘₐₓ+2S, where Wₘₐₓ is the maximum width of the MD contact.

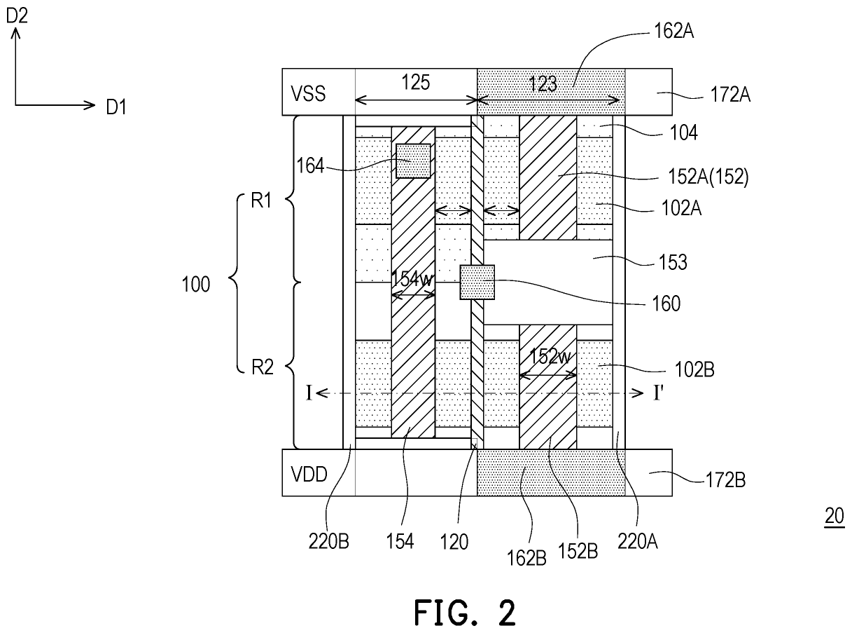

FIG. 2 is a simplified top-down layout view of a semiconductor device in accordance with some embodiments.

Referring to FIG. 2, a semiconductor device 20 is similar to the semiconductor device 10 of FIG. 1A. That is, the structures, materials, and functions of the semiconductor device 20 are similar to those of the semiconductor device 10, and thus the details are omitted herein. The main difference between the semiconductor device 20 and the semiconductor device 10 lies in that the semiconductor device 20 further includes a first dielectric gate structure 220A, a second dielectric gate structure 220B, a cut-MD (CMD) structure 153, a via-to-gate (VG) structure 160, a first via-to-MD (VD) structure 162A, a second VD structure 162B, a third VD structure 164, a first metal line 172A, and a second metal line 172B.

In detail, the first dielectric gate structure 220A may replace the position of the gate structure 120A of FIG. 1A, and the second dielectric gate structure 220B may replace the position of the gate structure 120B of FIG. 1A. In such embodiment, the first MD contact 152 is disposed between the gate structure 120 and the first dielectric gate structure 220A, while the second MD contact 154 is disposed between the gate structure 120 and the second dielectric gate structure 220B. Herein, the first and second dielectric gate structures 220A and 220B may be referred to as continuous poly on oxide definition edge (CPODE) structures, which is formed on edges of the active regions 102A and 102B such as the fins in a FinFET. The CPODE structures are formed on the edge of the semiconductor device 20, and are used to protect the ends of the fins 102A and 102B during processing. That is, the CPODE structures are not electrically connected as gates for the transistors but are instead “dummy” structures, having no function in the circuit. The CPODE structures cover and protect the ends of the fins 102A and 102B, providing additional reliability during processing. In some embodiments, the first and second dielectric gate structures 220A and 220B may be formed by removing the CPODE structures and the substrate 100 under the CPODE structures to form trenches, and filling in the trenches with a dielectric or insulating material. In this case, first and second dielectric gate structures 220A and 220B may avoid leakage between neighboring devices.

As shown in FIG. 2, the CMD structure 153 is used to divided the MD contact 152 into two segments 152A and 152B. The CMD structure 153 may be made of a dielectric material, and provide necessary electrical isolation in the semiconductor device The CMD structure 153 may include SiO, SiN, SiC, SiON, SiOC, SiCN, or other suitable materials. The CMD structure 153 may be formed by atomic layer deposition (ALD), physical vapor deposition (PVD), chemical vapor deposition (CVD), or other suitable process. In some embodiments, the CMD structure 153 may be formed after forming the MD contacts 152A and 152B. In some alternative embodiments, the CMD structure 153 may be formed before forming the MD contacts 152A and 152B according to process design.

In some embodiments, the VG structure 160 may disposed on the gate structure 120 for providing the gate voltage to the gate structure 120. In some embodiments, the VG structure 160 includes a liner, such as a diffusion barrier layer, an adhesion layer, or the like, and a conductive material. The liner may include Ti, TiN, Ta, TaN, the like, or a combination thereof. The conductive material may be Ti, TiN, TaN, Co, Ru, Pt, W, Al, Cu, or a combination thereof. The VG structure 160 may be formed by an electro-chemical plating process, CVD, PVD or the like.

In some embodiments, the first metal line 172A and the second metal line 172B extend along the first direction Dl. Herein, the first metal line 172A may be referred to as a power supply line (VSS), and the second metal line 172B may be referred to as another power supply line (VDD). The first VD structure 162A is vertically disposed between the MD contact 152A and the first metal line 172A, and the second VD structure 162B is vertically disposed between the MD contact 152B and the second metal line 172B. In this case, the first metal line 172A may be electrically connected to the MD contact 152A or the underlying S/D feature through the first VD structure 162A, and the second metal line 172B may be electrically connected to the MD contact 152B or the underlying S/D feature through the second VD structure 162B. In addition, the third VD structure 164 is disposed on and in contact with the second MD contact 154. It should be noted that, in the embodiment, the first VD structure 162A (or the second VD structure 162B) has an area greater than an area of the third VD structure 164. In this case, the resistance between the power supply lines (e.g., VDD and/or VSS) and the first VD structure 162A (or the second VD structure 162B) is reduced for the better power transfer and lower power consumption.

In some embodiments, the metal lines 172A and 172B may include a metal material, such as aluminum, copper, nickel, gold, silver, tungsten, or a combination thereof and formed by an electro-chemical plating process, CVD, PVD or the like. In some embodiments, the VD structures 162A, 162B, 164 include a liner, such as a diffusion barrier layer, an adhesion layer, or the like, and a conductive material. The liner may include Ti, TiN, Ta, TaN, the like, or a combination thereof. The conductive material may be Ti, TiN, TaN, Co, Ru, Pt, W, Al, Cu, or a combination thereof. The VD structures 162A, 162B, 164 may be formed by an electro-chemical plating process, CVD, PVD or the like. In one example, a damascene and/or dual damascene process is used to form the VD structures 162A, 162B, 164, and the metal lines 172A, 172B.

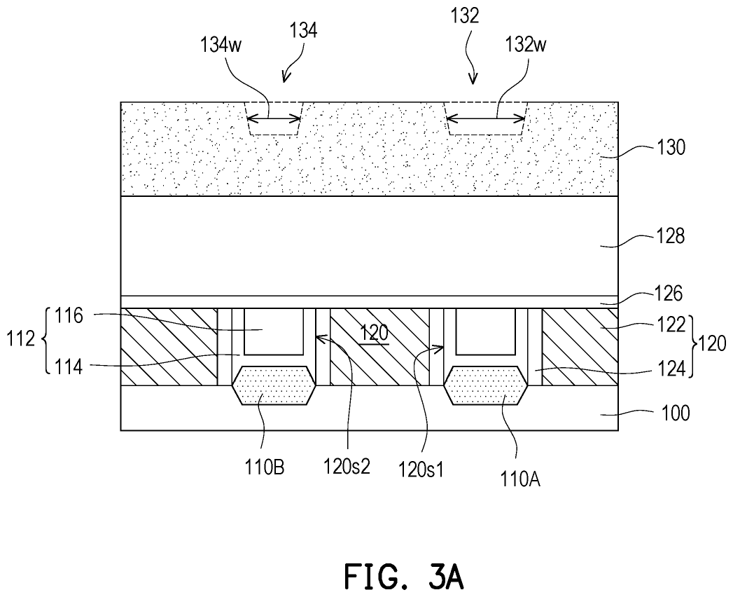

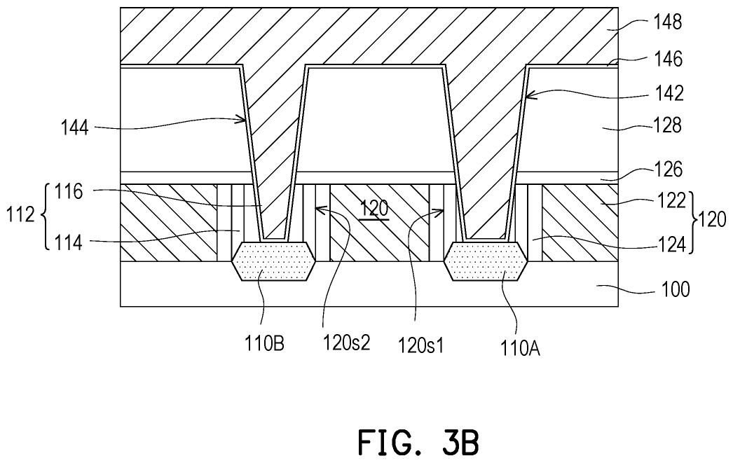

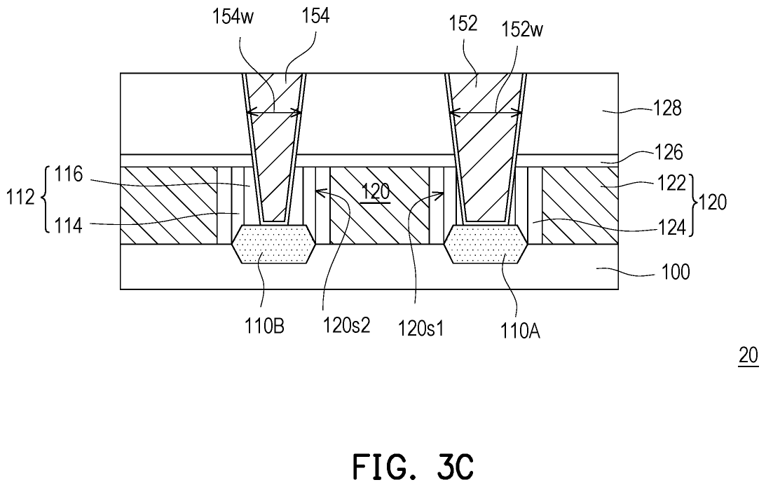

FIG. 3A to FIG. 3C are cross-sectional views of a method of forming the semiconductor device 20 in FIG. 2 taken along the line I-I′ in accordance with some embodiments. The semiconductor device 20 may be included in a microprocessor, a memory, and/or other IC devices. In some embodiments, the semiconductor device 20 is a portion of an IC chip, a system on chip (SoC), or portion thereof, that includes various passive and active microelectronic devices such as resistors, capacitors, inductors, diodes, p-type FETs (PFETs), n-type FETs (NFETs), metal-oxide-semiconductor FETs (MOSFETs), complementary MOS (CMOS) transistors, bipolar junction transistors (BJTs), laterally diffused MOS (LDMOS) transistors, high voltage transistors, high frequency transistors, other suitable components, or combinations thereof. The various transistors may be planar transistors or non-planar transistors, such as fin-like FETs (FinFETs) or gate-all-around (GAA) transistors depending on design requirements of the semiconductor device 20. FIG. 3A to FIG. 3C have been simplified for the sake of clarity to better understand the inventive concepts of the present disclosure. Additional features can be added in the semiconductor device 20, and some of the features described below can be replaced, modified, or eliminated in other embodiments of the semiconductor device 20.

Referred to FIG. 3A, the semiconductor device 20 has undergone FEOL processing where various IC devices, IC features, and/or IC components have been fabricated on a substrate (wafer) 100. In the depicted embodiment, the substrate 100 includes silicon. Alternatively, or additionally, the substrate 100 includes another elementary semiconductor, such as germanium; a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AlGaAs, GalnAs, GaInP, and/or GaInAsP; or combinations thereof. Alternatively, the substrate 100 is a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other suitable methods. The substrate 100 can include doped regions formed by an ion implantation process, a diffusion process, and/or other suitable doping process depending on design requirements of the semiconductor device 20. In some embodiments, the substrate 100 includes p-type doped regions (for example, p-type wells) doped with p-type dopants, such as boron, indium, other p-type dopant, or combinations thereof. In some embodiments, the substrate 100 includes n-type doped regions (for example, n-type wells) doped with n-type dopants, such as phosphorus, arsenic, other n-type dopant, or combinations thereof. In some embodiments, the substrate 100 includes doped regions formed with a combination of p-type dopants and n-type dopants. The various doped regions can be formed directly on and/or in the substrate 100, for example, providing a p-well structure, an n-well structure, a dual-well structure, a raised structure, or combinations thereof.

In the depicted embodiment, the various IC features and/or IC components include the gate structure 120 disposed over the substrate 100, where the gate structure 120 has a metal gate (MG) stack 122 and a gate spacer 124. In furtherance of the depicted embodiment, the various IC features and/or IC components include a first S/D feature 110A, a second S/D feature 110B, an etch stop layer (ESL) 114, and a dielectric layer 116 (e.g., ILD layer), which are described further below. In some embodiments, a transistor of the semiconductor device 20 includes the gate structure 120 disposed between a source region (e.g., first S/D feature 110A) and a drain region (e.g., second S/D feature 110B), where a channel region is defined in the substrate 100 between the source region and the drain region. The gate structure 120 engages the channel region, such that current can flow between the source region and the drain region (collectively referred to as source/drain regions) (i.e., between the first S/D feature 110A and the second S/D feature 110B) during operation. In FIG. 2, the various IC components and their respective configurations is merely exemplary. The present disclosure contemplates the semiconductor device 20 having any combination of IC components and/or IC devices and any configuration of such IC components and/or IC devices fabricated by FEOL processing.

The metal gate stack 122 is formed by deposition processes, lithography processes, etching processes, other suitable processes, or combinations thereof. The deposition processes include chemical vapor deposition (CVD), physical vapor deposition (PVD), atomic layer deposition (ALD), high density plasma CVD (HDPCVD), metal organic CVD (MOCVD), remote plasma CVD (RPCVD), plasma enhanced CVD (PECVD), low-pressure CVD (LPCVD), atomic layer CVD (ALCVD), atmospheric pressure CVD (APCVD), plasma enhanced ALD (PEALD), plating, other suitable methods, or combinations thereof. The lithography patterning processes include resist coating (for example, spin-on coating), soft baking, mask aligning, exposure, post-exposure baking, developing the resist, rinsing, drying (for example, hard baking), other suitable processes, or combinations thereof. Alternatively, the lithography exposure process is assisted, implemented, or replaced by other methods, such as maskless lithography, electron-beam writing, or ion-beam writing. The etching processes include dry etching processes, wet etching processes, other etching processes, or combinations thereof. The metal gate stack 122 is fabricated according to a gate last process, a gate first process, or a hybrid gate last/gate first process. In gate last processes, the metal gate stack 122 includes dummy gate stacks that are subsequently, partially or completely, replaced with the metal gate stack 122, respectively. The dummy gate stacks include, for example, an interfacial layer (including, for example, silicon oxide) and a dummy gate electrode layer (including, for example, polysilicon). In such embodiments, the dummy gate electrode layer is removed, thereby forming gate openings that are subsequently filled with the metal gate stack 122.

The gate spacers 144 are disposed adjacent to (for example, along sidewalls of) the metal gate stack 122, respectively. The gate spacers 144 are formed by any suitable process and include a dielectric material. The dielectric material can include silicon, oxygen, carbon, nitrogen, other suitable material, or combinations thereof (for example, silicon oxide, silicon nitride, silicon oxynitride, or silicon carbide). For example, a dielectric layer including silicon and nitrogen, such as a silicon nitride layer, can be deposited over the substrate 100 and subsequently anisotropically etched to form the gate spacers 144. In some embodiments, the gate spacers 144 include a multi-layer structure, such as a first dielectric layer that includes silicon nitride and a second dielectric layer that includes silicon oxide. In some embodiments, more than one set of spacers, such as seal spacers, offset spacers, sacrificial spacers, dummy spacers, and/or main spacers, are formed adjacent to the metal gate stack 122. In such embodiments, the various sets of spacers can include materials having different etch rates. For example, a first dielectric layer including silicon and oxygen (for example, silicon oxide) can be deposited over the substrate 100 and subsequently anisotropically etched to form a first spacer set adjacent to the metal gate stack 122 (or dummy metal gate stacks, in some embodiments), and a second dielectric layer including silicon and nitrogen (for example, silicon nitride) can be deposited over the substrate 100 and subsequently anisotropically etched to form a second spacer set adjacent to the first spacer set. Implantation, diffusion, and/or annealing processes may be performed to form lightly doped source and drain (LDD) features and/or heavily doped source and drain (HDD) features in the substrate 100 before and/or after forming the gate spacers 144, depending on design requirements of the semiconductor device 20.

The first S/D feature 110A is disposed on the substrate 100 at the first side 120s1 of the gate structure 120, and the second S/D feature 110B is disposed on the substrate 100 at the second side 120s2 of the gate structure 120. In some embodiments, a semiconductor material is epitaxially grown on and/or from the substrate 100 to form the first and second S/D features 110A and 110B. In some embodiments, an etching process is performed on source/drain regions of the substrate 100 to form source/drain recesses, where the first and second S/D features 110A and 110B are grown to fill the source/drain recesses. An epitaxy process can implement CVD deposition techniques (for example, vapor-phase epitaxy (VPE), ultra-high vacuum CVD (UHV-CVD), LPCVD, and/or PECVD), molecular beam epitaxy, other suitable SEG processes, or combinations thereof. The epitaxy process can use gaseous and/or liquid precursors, which interact with the composition of the substrate 100. The first and second S/D features 110A, 130B are doped with n-type dopants and/or p-type dopants. In some embodiments, the first and second S/D features 110A and 110B are epitaxial layers including silicon and/or carbon, where the silicon-comprising epitaxial layers or the silicon-carbon-comprising epitaxial layers are doped with phosphorous, other n-type dopant, or combinations thereof. In some embodiments, the first and second S/D features 110A and 110B are epitaxial layers including silicon and germanium, where the silicon-and-germanium-compromising epitaxial layers are doped with boron, other p-type dopant, or combinations thereof. In some embodiments, the first and second S/D features 110A and 110B include materials and/or dopants that achieve desired tensile stress and/or compressive stress in the channel regions. In some embodiments, the first and second S/D features 110A and 110B are doped during deposition by adding impurities to a source material of the epitaxy process. In some embodiments, the first and second S/D features 110A and 110B are doped by an ion implantation process subsequent to a deposition process. In some embodiments, annealing processes are performed to activate dopants in the first and second S/D features 110A and 110B and/or other source/drain regions of the semiconductor device 20 (for example, HDD regions and/or LDD regions).

The ESL 114 is disposed over the substrate 100, the gate structure 120, and the first and second S/D features 110A and 110B. The dielectric layer 116 is disposed over the ESL 114. In the embodiment, the ESL 114 and the dielectric layer 116 may be collectively referred to as a filling layer 112. The filling layer 112 may be disposed on the first and second S/D features 110A and 110B to laterally surround the gate structure 120. The dielectric layer 116 includes a dielectric material including, for example, silicon oxide, silicon nitride, silicon oxynitride, tetraethyl orthosilicate (TEOS) oxide, PSG, BPSG, low-k dielectric material, other suitable dielectric material, or combinations thereof. Low-k dielectric material generally refers to dielectric materials having a low dielectric constant relative to the dielectric constant of silicon dioxide. For example, low-k dielectric material has a dielectric constant less than about 3.9. In some examples, low-k dielectric material has a dielectric constant less than about 2.5, which can be referred to as extreme low-k dielectric material. Exemplary low-k dielectric materials include fluorosilicate glass (FSG), carbon doped silicon oxide, Black Diamond® (Applied Materials of Santa Clara, Calif.), Xerogel, Aerogel, amorphous fluorinated carbon, Parylene, BCB, SILK (Dow Chemical, Midland, Mich.), polyimide, other low-k dielectric material, or combinations thereof. In the depicted embodiment, the dielectric layer 116 includes a low-k dielectric material and is generally referred to as a low-k dielectric layer. The ESL 114 includes a material different than the dielectric layer 116, such as a dielectric material that is different than the dielectric material of the dielectric layer 116. The dielectric layer 116 and/or the ESL 114 may include a multilayer structure having multiple dielectric materials. In the depicted embodiment, where the dielectric layer 116 includes silicon and oxygen (for example, SiCOH, SiOx, or other silicon-and-oxygen comprising material) (and can thus be referred to as a silicon oxide layer), the ESL 114 includes silicon and nitrogen and/or carbon (for example, SiN, SiCN, SiCON, SiON, SiC, and/or SiCO) (and can thus be referred to as a silicon nitride layer). The dielectric layer 116 and/or the ESL 114 are formed over the substrate 100 by a deposition process, such as CVD, PVD, ALD, HDPCVD, MOCVD, RPCVD, PECVD, LPCVD, ALCVD, APCVD, PEALD, other suitable methods, or combinations thereof. In some embodiments, the dielectric layer 116 is formed by a flowable CVD (FCVD) process that includes, for example, depositing a flowable material over the substrate 100 and converting the flowable material to a solid material by a suitable technique, such as thermal annealing and/or treating the flowable material with ultraviolet radiation. Subsequent to the deposition of the dielectric layer 116 and/or the ESL 114, a CMP process and/or other planarization process is performed, such that the dielectric layer 116, the ESL 114, and/or the gate structure 120 have substantially planar surfaces. That is, the filling layer 112 has a top surface substantially level with a top surface of the gate structure 120.

After the CMP process, an ESL 126, a dielectric layer 128, and a mask layer 130 are formed on the gate structure 120 and the filling layer 112 in order. The ESL 126 is similar to the ESL 114, and the dielectric layer 128 is similar to the dielectric layer 116. The ESL 126 and/or the dielectric layer 128 may thus be configured and formed as described with reference to the ESL 114 and the dielectric layer 116 above. Thus, details thereof are omitted here. In some embodiments, the mask layer 130 may include a photoresist which may be formed by spin-on coating.

Referring to FIG. 3A to FIG. 3B, a direct patterning process is performed to form a first opening 142 and a second opening 144 in the dielectric layer 128, the ESL layer 126, and the filling layer 122. Specifically, the direct patterning process may include following steps. First, an extreme UV (EUV) photolithography process is performed to form a first groove 132 and a second groove 134 in the mask layer 130. As shown in FIG. 3A, the first groove 132 may correspond to the first S/D feature 110A and the second groove 134 may correspond to the second S/D feature 110B. In some embodiments, the first groove 132 has a width 132w greater than a width 134w of the second groove 134, and the first groove 132 and the second groove 134 both extend partially into the mask layer 130. In some embodiments, the width 132w may be in a range of 10 nm to 20 nm, such as 16 nm, and the width 134w may be in a range of 10 nm to 20 nm, such as 14 nm.

In some embodiments, the EUV photolithography process may be performed by generating electromagnetic radiation in an atmosphere of H₂ plasma to produce an incident radiation beam having a wavelength in a desired range. The electromagnetic radiation may be generated with a plasma source such as xenon, oxygen, lithium, combinations thereof, or the like. A mask having the pattern of the first groove 132 and the second groove 134 patterns the incident radiation beam with a pattern that will be formed in the photoresist layer 130. The mask may be a transmissive mask, a reflective mask (sometimes referred to as a “reticle”), an optical proximity correction (OPC) mask, or the like. Optics, such as a projection optics box (POB), are then used to collect the patterned radiation beam, magnify or reduce the patterned radiation beam, and then project the patterned radiation beam on the photoresist layer 130, thereby patterning the photoresist layer 130 with the pattern of the first groove 132 and the second groove 134.

Next, an etching process is performed by using the mask layer 130 as a mask to transfer the pattern of the photoresist layer 130 to the dielectric layer 128. Specifically, portions of the photoresist layer 130, the dielectric layer 128, the ESL 126, and the filling layer 112 are removed to extend the first groove 132 downward to form the first opening 142, and extend second groove 134 downward to form the second opening 144. In this case, as shown in FIG. 3B, the first opening 142 may expose the first S/D feature 110A, and the second opening 144 may expose the second S/D feature 110B. In some embodiments, the etching process may include a dry etching (e.g., reactive ion etching (RIE) or inductively coupled plasma (ICP) etching), a wet etching, and/or other etching methods. When the etching process is completed, a subsequent plasma ashing and a wet clean may be applied to remove the remaining mask layer 130 (e.g., remaining photoresist).

It should be noted that, in the present embodiment, the direct patterning process is used for forming the MD contacts with different widths. Compared with the conventional self-aligned contact (SAC) process, the direct patterning process (i.e., non-SAC process) can form the contacts with different widths at different positions to achieve of dynamically adjusting the MD contact width and the poly pitch (CPP). In some embodiments, the next-generation lithography such as the EUV photolithography process can facilitate the formation of the MD contacts with arbitrary shapes and very small dimensions in the direct patterning processes. Alternatively, other next-generation lithography techniques such as deep ultraviolet (DUV) lithography, X-ray lithography, soft X-ray (SX) lithography, ion beam projection lithography, electron-beam projection lithography, or the like may be used in the direct patterning processes.

Afterwards, a conductive barrier layer 146 is formed to conformally cover the inner surfaces of the first opening 142 and the second opening 144, and further extends to cover the top surface of the dielectric layer 128. In some embodiments, the conductive barrier layer 146 can function as both a barrier layer and an adhesion layer to the subsequently formed conductive material 148, where the conductive barrier layer 146 prevents or reduces the reflow/diffusion of the conductive material 148 to the surrounding layers (e.g., the dielectric layer layers 116, 128, the ESL layers 114, 126), and promotes the adhesion of the conductive material 148 to the surrounding layers. In some embodiments, the conductive barrier layer 146 may be made of Ta, Ti, TiN, TaN, or the like. The conductive barrier layer 146 can be deposited by performing one or more of chemical vapor deposition (CVD), physical vapor deposition (PVD), atomic layer deposition (ALD), sputtering, e-beam evaporation, or any combination thereof.

The conductive material 148 is formed over the conductive barrier layer 146 to fill into the first opening 142 and the second opening 144. The conductive material 148 may include cobalt (Co), tungsten (W), ruthenium (Ru), aluminum (Al), copper (Cu), or other suitable conductors, and be deposited by performing a suitable deposition process, such as chemical vapor deposition (CVD), physical vapor deposition (PVD), atomic layer deposition (ALD), sputtering, e-beam evaporation, or any combination thereof. Alternatively, the conductive material 148 may include copper (Cu), copper manganese (CuMn), copper aluminum (CuAl), and the like, and an electro-chemical plating (ECP) process may be applied. In addition, silicide layers (not shown), such as nickel silicide (NiSi), cobalt silicide (CoSi), titanium silicide (TiSi), tungsten silicide (WSi), molybdenum silicide (MoSi), platinum silicide (PtSi), palladium silicide (PdSi) or the like, may be formed between the conductive material 148 and the S/D features 110A/110B for reducing the resistance.

Referring to FIG. 3B and FIG. 3C, a planarization process is performed to remove any excessive conductive material 148 and conductive barrier layer 146 over the dielectric layer 128, thereby forming a first MD contact 152 in the first opening 142 and form a second MD contact 154 in the second opening 144. In some embodiments, the planarization process includes a chemical mechanical polishing (CMP) process, an etching back process, or a combination thereof. After the planarization process, the first MD contact 152, the second MD contact 154, and the dielectric layer 128 may have substantially planar surfaces. In some embodiments, the first MD contact 152 has the first width 152w greater than the second width 154w of the second MD contact 154, so that the resistance between the first MD contact 152 and the first S/D feature 110A is reduced, thereby decreasing the RC delay and improving device performance.

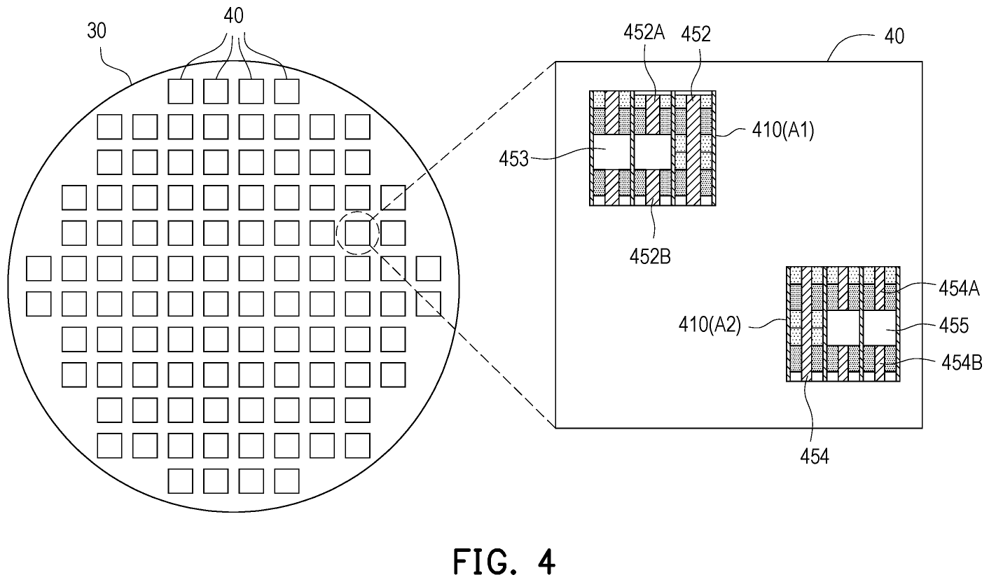

FIG. 4 is a simplified top-down layout view of a semiconductor device in accordance with some alternative embodiments.

Referring to FIG. 4, a wafer 30 is provided. In some embodiments, the wafer 30 may include a semiconductor wafer, such as silicon wafer. The wafer 30 may be divided into a plurality of dies 40 by a plurality of scribe lines (not shown). In this case, the dies 40 may be arranged in an array with a plurality of columns and a plurality of rows. As shown in the enlarged view of FIG. 4, the die 40 may include a first cell 410 and a second cell 420. In some embodiments, the first cell 410 may include MD contacts 452 with the large width and large poly pitch (CPP) for some blocks of the performance requirement (e.g., high speed and/or large power requirement). On the other hands, the second cell 420 may include MD contacts 454 with the small width and small poly pitch (CPP) for other blocks of the area shrinkage requirement. In such embodiment, the first cell 410 may have an area A1 greater than an area A2 of the second cell 420. That is, the present embodiment can increase or decrease the width of the MD contacts according to the design requirements, thereby improving the device performance and miniaturizing devices in the same die/area. Further, the first cell 410 may also include a cut-MD (CMD) structure 453 used to divided the MD contact 452 into two segments 452A and 452B, and the second cell 420 may also include a cut-MD (CMD) structure 455 used to divided the MD contact 454 into two segments 454A and 454B. Although only one first cell 410 and one second cell 420 are illustrated in FIG. 4, the embodiments of the present disclosure are not limited thereto. In other embodiments, the number of the cells may be adjusted according to design requirements, and the location of the cells is also not limited.

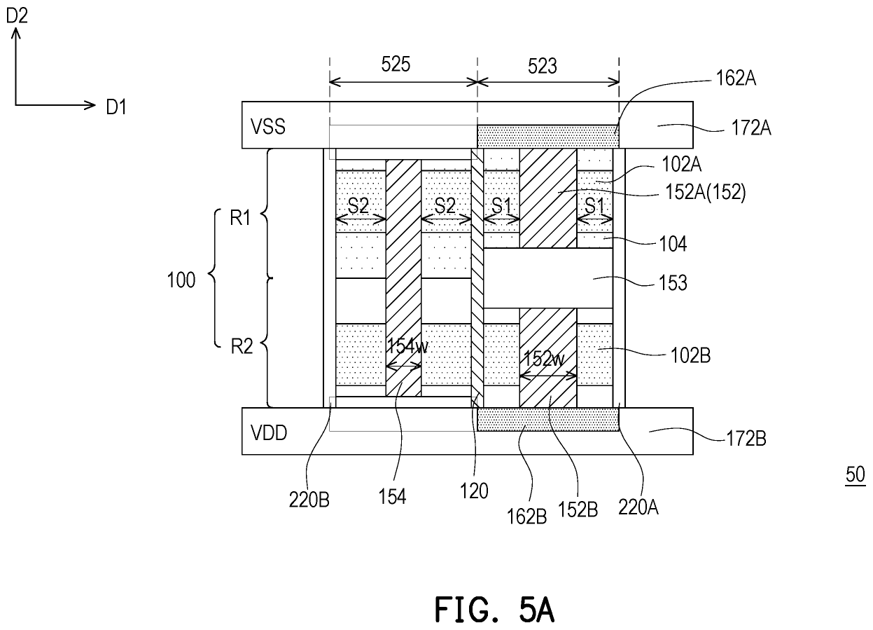

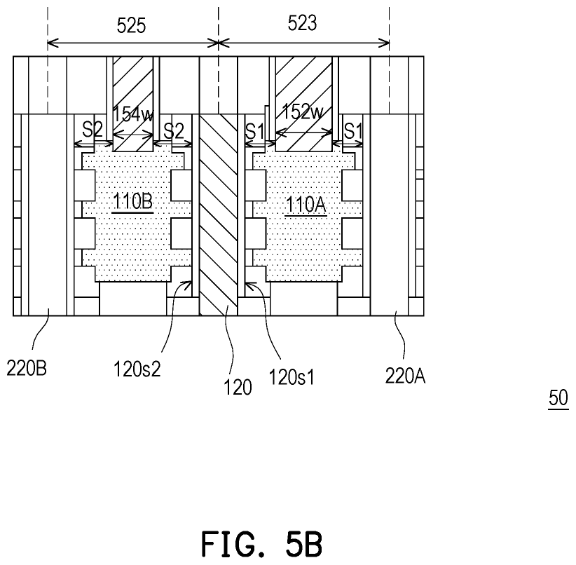

FIG. 5A is a simplified top-down layout view of a semiconductor device in accordance with some other embodiments. FIG. 5B is a cross-sectional view of a semiconductor device in FIG. 5A.

Referring to FIG. 5A and FIG. 5B, a semiconductor device 50 is similar to the semiconductor device 10 of FIG. 1B and the semiconductor device 20 of FIG. 2. That is, the structures, materials, and functions of the semiconductor device 50 are similar to those of the semiconductor devices 10, 20, and thus the details are omitted herein. The main difference between the semiconductor device 50 and the semiconductor devices 10, 20 lies in that a first pitch (also known as a poly pitch (CPP)) 523 is substantially equal to a second pitch 525 while the first width 152w of the first MD contact 152 is greater than the second width 154w of the second MD contact 154. In such embodiment, the second space S2 between the second MD contact 154 and the gate structure 120 may be greater than the first space S1 between the first MD contact 152 and the gate structure 120. Therefore, as shown in FIG. 5A, the capacitance between the gate structure 120 and the second MD contact 154 may be reduced, thereby decreasing the RC delay and improving device performance. Further, as shown in FIG. 5B, the contact area between the first MD contact 152 and the first S/D feature 110A is greater than the contact area between the second MD contact 154 and the second S/D feature 110B, so that the resistance between the first MD contact 152 and the first S/D feature 110A is reduced, thereby decreasing the RC delay and improving the reliability. In addition, the smaller second width 154w or the smaller second pitch 525 can be beneficial for the area shrinking. In such embodiment, the first S/D feature 110A may be referred to as a source region, while the second S/D feature 110B may be referred to as a drain region.

In some embodiments, the first pitch 523 may be in a range of 40 nm to 60 nm, such as 48 nm; the second pitch 525 may be in a range of 40 nm to 60 nm, such as 48 nm, and a ratio of the first pitch 523 to the second pitch 525 may be in a range of 1 to 1.5. In some embodiments, the first space Si may be in a range of 5 nm to 10 nm, such as 10 nm; the second space S2 may be in a range of 5 nm to 10 nm, such as 10 nm; and a ratio of the first space S1 to the second space S2 may be in a range of 1 to 2. In some embodiments, the first width 152w may be in a range of 10 nm to 20 nm, such as 16 nm; the s second width 154w may be in a range of 10 nm to 20 nm, such as 12 nm; and a ratio of the first width 152w to the second width 154w may be in a range of 1 to 2.

As mentioned above, the first width 152w may be greater than the second width 154w. In such embodiment, when the first pitch 523 and the second pitch 525 are regarded as a fixed pitch (CPP), the second width 154w is regarded as a fixed width (W), the first width 152w may be adjusted to be (W+ΔW), where ΔW is a width variation. As such, the first space S1 and the second space S2 may be represented by the following formula:

S1=½(CPP−Wₚₒ−W−ΔW), where Wₚₒ is the width of the gate structure 120, W is the fixed second width 154w, and AW is the width variation.
S2=½(CPP−Wₚₒ−W), where Wₚₒ is the width of the gate structure 120, and W is the fixed second width 154w.

For example, when the width (Wₚₒ) of the gate structure 120 is fixed to 12 nm, the second pitch 525 (i.e., CPP) is 48, and the second width 154w of the second MD contact 154 is fixed to 12 nm, the second space S2 is calculated as 12 nm. In addition, the first space S1 may be dynamically adjusted to 1/2(24−ΔW) nm.

In some alternative embodiments, when the first space S1 and/or the second space S2 becomes smaller, there may be a short issue between the gate structure 120 and the MD contact (152/154). In this case, the minimum value of the first space S1 and the second space S2 may be represented by the following formula:

½(CPP−Wₚₒ−W−ΔW)≥S1ₘᵢₙ, where S1ₘᵢₙ is the minimum width of the first space S1.
½(CPP−Wₚₒ−W)≥S2ₘᵢₙ, where S2ₘᵢₙ is the minimum width of the second space S2.

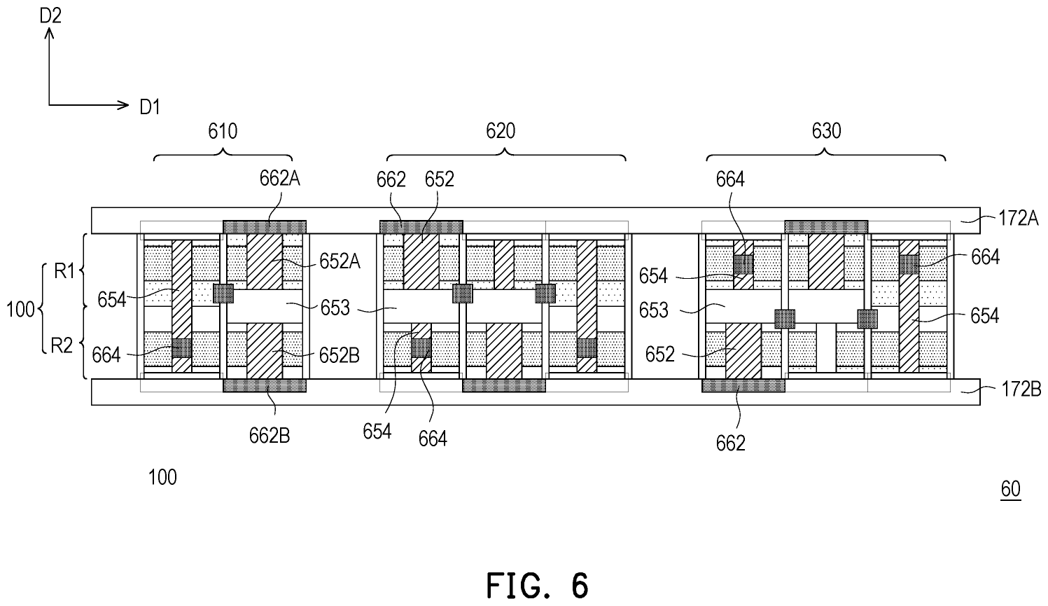

FIG. 6 is a simplified top-down layout view of a semiconductor device in accordance with some embodiments.

Referring to FIG. 6, a semiconductor device 60 may include a first cell 610, a second cell 620, and a third cell 630. In detail, the first cell 610 may include a CMD structure 653 separating a first MD contact 652A from a second MD 652B. The first MD contact 652A may be electrically connected to the first metal line 172A through a first VD structure 662A, and the second MD contact 652B may be electrically connected to the second metal line 172B through a second VD structure 662B. The first cell 610 further includes a third MD contact 654 having a width less than a width of the MD contacts 652A and 652B. The third MD contact 654 may be electrically connected to another cell through a third VD structure 664.

The second cell 620 is similar to the first cell 610, and the main difference between the second cell 620 and the first cell 610 lies in that one MD contact 652 and another MD contact 654 with different widths is separated by the CMD structure 653 in the second cell 620. In some embodiments, the MD contact 652 may have a width greater than a width of the MD contact 654. The MD contact 652 may be electrically connected to the first metal line 172A through the VD structure 662, and the MD contacts 654 may be electrically connected to another cell through the VD structure 664.

The third cell 630 is similar to the second cell 620, and the main difference between the third cell 630 and the second cell 620 lies in the different configurations of the MD contacts 652 and 654. That is, in the present embodiment, the width and the configuration of the MD contact may be adjusted according to the design needs to meet the customized requirements, thereby achieving the effects of low resistance, low capacitance, and reduced chip area.

According to some embodiments, a semiconductor device includes: at least one gate structure having a first side and a second side opposite to each other; a first source/drain (S/D) feature disposed at the first side of the at least one gate structure; a second S/D feature disposed at the second side of the at least one gate structure; a first metal-to-drain/source (MD) contact disposed on the first S/D feature; and a second MD contact disposed on the second S/D feature, wherein a contact area between the first MD contact and the first S/D feature is greater than a contact area between the second MD contact and the second S/D feature.

According to some embodiments, a method of forming a semiconductor device includes: forming at least one gate structure having a first side and a second side opposite to each other on a substrate; forming a first S/D feature on the substrate at the first side of the at least one gate structure; forming a second S/D feature disposed on the substrate at the second side of the at least one gate structure; forming a filling layer on the first and second S/D features; forming a dielectric layer and a mask layer on the filling layer and the at least one gate structure; performing a direct patterning process to form a first opening and a second opening with different widths in the dielectric layer and the filling layer, wherein the first opening exposes the first S/D feature and the second opening exposes the second S/D feature; and forming a conductive material to fill in the first and second openings.

According to some embodiments, a semiconductor device includes: a conductive gate structure having a first side and a second side opposite to each other; a first dielectric gate structure disposed at the first side of the conductive gate structure; a second dielectric gate structure disposed at the second side of the conductive gate structure; a first MD contact disposed between the conductive gate structure and the first dielectric gate structure; and a second MD contact disposed between the conductive gate structure and the second dielectric gate structure, wherein the first and second MD contacts have different widths.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
at least one gate structure having a first side and a second side opposite to each other;
a first source/drain (S/D) feature disposed at the first side of the at least one gate structure;
a second S/D feature disposed at the second side of the at least one gate structure;
a first metal-to-drain/source (MD) contact disposed on the first S/D feature; and
a second MD contact disposed on the second S/D feature, wherein a contact area between the first MD contact and the first S/D feature is greater than a contact area between the second MD contact and the second S/D feature.

2. The semiconductor device of claim 1, wherein the first MD contact has a first width greater than a second width of the second MD contact.

3. The semiconductor device of claim 1, wherein a ratio of a first width of the first MD contact to a second width of the second MD contact is in a range of 1 to 2.

4. The semiconductor device of claim 1, wherein a first space between the first MD contact and the at least one gate structure is substantially equal to a second space between the second MD contact and the at least one gate structure.

5. The semiconductor device of claim 1, wherein a first space between the first MD contact and the at least one gate structure is less than a second space between the second MD contact and the at least one gate structure.

6. The semiconductor device of claim 1, further comprising:
a first via-to-MD (VD) structure disposed on the first MD contact;
a second VD structure disposed on the second MD contact, wherein the second VD structure has an area less than an area of the first VD structure; and
a metal line disposed on the first VD structure, wherein the metal line is electrically connected to the first S/D feature through the first VD structure and the first MD contact.

7. The semiconductor device of claim 6, wherein the metal line extends along a first direction, and the at least one gate structure, the first MD contact, and the second MD contact extend along a second direction substantially perpendicular to the first direction.

8. A method of forming a semiconductor device, comprising:
forming at least one gate structure having a first side and a second side opposite to each other on a substrate;
forming a first S/D feature on the substrate at the first side of the at least one gate structure;
forming a second S/D feature disposed on the substrate at the second side of the at least one gate structure;
forming a filling layer on the first and second S/D features;
forming a dielectric layer and a mask layer on the filling layer and the at least one gate structure;
performing a direct patterning process to form a first opening and a second opening with different widths in the dielectric layer and the filling layer, wherein the first opening exposes the first S/D feature and the second opening exposes the second S/D feature; and
forming a conductive material to fill in the first and second openings.

9. The method of claim 8, wherein the first opening has a width greater than a width of the second opening.

10. The method of claim 8, wherein a ratio of a width of the first opening to a width of the second opening is in a range of 1 to 2.

11. The method of claim 8, further comprising: performing a planarization process on the conductive material to form a first MD contact in the first opening and form a second MD contact in the second opening.

12. The method of claim 8, wherein the filling layer has a top surface substantially level with a top surface of the at least one gate structure.

13. The method of claim 8, wherein the direct patterning process comprises:
performing an extreme UV (EUV) photolithography process to form a first groove and a second groove in the mask layer, wherein the first groove corresponds to the first S/D feature and the second groove corresponds to the second S/D feature; and
performing an etching process by using the mask layer as a mask to extend the first groove downward to form the first opening exposing the first S/D feature, and extend the second groove downward to form the second opening exposing the second S/D feature.

14. A semiconductor device, comprising:
a conductive gate structure having a first side and a second side opposite to each other;
a first dielectric gate structure disposed at the first side of the conductive gate structure;
a second dielectric gate structure disposed at the second side of the conductive gate structure;
a first MD contact disposed between the conductive gate structure and the first dielectric gate structure; and
a second MD contact disposed between the conductive gate structure and the second dielectric gate structure, wherein the first and second MD contacts have different widths.

15. The semiconductor device of claim 14, wherein the first MD contact has a first width greater than a second width of the second MD contact.

16. The semiconductor device of claim 15, wherein
a first pitch between the conductive gate structure and the first dielectric gate structure is substantially equal to a second pitch between the conductive gate structure and the second dielectric gate structure, and
a first space between the first MD contact and the conductive gate structure is less than a second space between the second MD contact and the conductive gate structure.

17. The semiconductor device of claim 15, wherein
a first space between the first MD contact and the conductive gate structure is substantially equal to a second space between the second MD contact and the conductive gate structure, and
a first pitch between the conductive gate structure and the first dielectric gate structure is greater than a second pitch between the conductive gate structure and the second dielectric gate structure.

18. The semiconductor device of claim 15, further comprising:
a first VD structure disposed on the first MD contact;
a second VD structure disposed on the second MD contact, wherein the second VD structure has an area less than an area of the first VD structure; and
a metal line disposed on the first VD structure, wherein the metal line is electrically connected to the first MD contact through the first VD structure.

19. The semiconductor device of claim 18, further comprising:
a third MD contact disposed between the conductive gate structure and the first dielectric gate structure; and
a fourth MD contact disposed between the conductive gate structure and the second dielectric gate structure;
a first cut-MD (CMD) structure separating the first MD contact from the third MD contact; and
a second CMD structure separating the second MD contact from the fourth MD contact.

20. The semiconductor device of claim 19, wherein the first MD contact and the third MD contact have different widths, while second MD contact and the fourth MD contact have different widths.
